(19) United States
(12) Patent Application Publication
(10) Pub. No.: US 2012/0104570 A1
(43) Pub. Date: May 3, 2012

(54) SEMICONDUCTOR PACKAGE MODULE

(75) Inventor: Jung Woo KIM, Hwaseong (KR)

(73) Assignee: SAMSUNG ELECTRO-MECHANICS CO., LTD., Gyunggi-do (KR)

(21) Appl. No.: 13/117,763

(22) Filed: May 27, 2011

(30) Foreign Application Priority Data
Nov. 1, 2010 (KR) 10-2010-0107768

(51) Int. Cl. H01L 23/552

(52) U.S. Cl. 257/659; 257/E23.114

(57) ABSTRACT

There is provided a semiconductor package module allowing a shield of a semiconductor package to be easily grounded and securing bonding reliability between the shield and a ground pattern. The semiconductor package module includes a semiconductor package having a shield formed on an upper surface thereof and side surfaces thereof; a main substrate having at least one ground electrode formed on a surface thereof and having the semiconductor package mounted thereon; and a bonding part bonding the ground electrode to the shield to electrically connect the ground electrode to the shield.

### CROSS-REFERENCE TO RELATED APPLICATIONS

This application claims the priority of Korean Patent Application No. 10-2010-0107768 filed on Nov. 1, 2010, in the Korean Intellectual Property Office, the disclosure of which is incorporated herein by reference.

### BACKGROUND OF THE INVENTION

1. Field of the Invention

The present invention relates to a semiconductor package module, and more particularly, to a semiconductor package module including a shielding member capable of shielding electromagnetic waves while simultaneously protecting a passive element, a semiconductor chip, or the like, included in a package from an external environment.

2. Description of the Related Art

In accordance with a recent rapid increase in the demand for portable apparatuses in an electronic product market, the demand for compact, light-weight electronic components mounted within these products has continuously increasing.

In order to manufacture compact, light-weight electronic components, a system on chip (SOC) technology integrating a plurality of individual elements in a single chip, a system in package (SIP) technology integrating a plurality of individual elements in a single package, or the like, as well as a technology for reducing the individual sizes of mounting components have been required.

Particularly, it has been demanded that a high frequency semiconductor package handling a high frequency signal such as a portable TV (DMB or DVB) module or a network module includes various electromagnetic shielding structures in order to implement excellent electromagnetic interference (EMI) and electromagnetic susceptibility (EMS) characteristics as well as a compact size.

In a general high frequency semiconductor package, a structure for mounting individual elements on a substrate and then forming a shield covering these individual elements is well known as a structure for shielding high frequency. The shield applied to the general high frequency semiconductor package not only covers all of the individual elements to protect the electronic elements therein from external shocks, but also is electrically connected to ground to promote the electromagnetic wave shielding.

The shield according to the related art has been configured to be electrically connected to a ground pattern. Accordingly, it was difficult to electrically connect the ground pattern formed on an upper surface of the substrate to the shield.

In addition, according to the related art, since the ground pattern of the substrate was directly electrically connected to the shield, a connection portion therebetween was formed by a very fine pattern, whereby the connection portion was damaged due, to shocks, or the like.

### SUMMARY OF THE INVENTION

An aspect of the present invention provides a semiconductor package module including an electromagnetic shielding structure having excellent electromagnetic interference (EMI) and electromagnetic susceptibility (EMS) characteristics, while protecting individual elements therein from shocks.

Another aspect of the present invention provides a semiconductor package module capable of easily grounding a shield.

Another aspect of the present invention provides a semiconductor package module capable of securing bonding reliability between a shield and a ground pattern.

According to an aspect of the present invention, there is provided a semiconductor package module including: a semiconductor package having a shield formed on an upper surface thereof and side surfaces thereof; a main substrate having at least one ground pad formed on a surface thereof and having the semiconductor package mounted thereon; and a bonding part bonding the ground pad to the shield to electrically connect the ground pad to the shield.

The ground pad may be disposed along an outer edge of the semiconductor package.

The ground pad may have an elongated has shape along an outer edge of the semiconductor package.

The ground pad may include a plurality of ground pads arranged in a row along an outer edge of the semiconductor package.

The ground pad may include a plurality of ground pads each arranged in a corner of the semiconductor package along an outer edge of the semiconductor package.

The around pad may include a protrusion part protruding in an inward manner so as to be disposed below the semiconductor package, the protrusion part being electrically connected to at least one external connection terminal provided on the semiconductor package.

The semiconductor package may include: a substrate; and at least one electronic component mounted on a surface of the substrate. The shield may have the electronic component received therein and be coupled to the substrate so as to be electrically insulated from a circuit pattern formed on the substrate.

The semiconductor package module may further include an insulating molding part sealing a space between the substrate and the shield.

The shield may have at least one side wall protruding downwardly of the substrate.

A portion of a side wall of the shield, corresponding to a position of the ground pad formed on the main substrate, may protrude downwardly of the substrate.

A distance, by which the shield is protruded downwardly of the substrate, may correspond to a distance from a lower surface of the semiconductor package to an upper surface of the main substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view showing a semiconductor package module according to an exemplary embodiment of the present invention;

FIG. 2 is a cut-away perspective view showing an inner portion of the semiconductor package module shown in FIG. 1;

FIG. 3 is an exploded perspective view of the semiconductor package module shown in FIG. 2;

FIG. 4A. is a perspective view schematically showing a semiconductor package module according to another exemplary embodiment of the present invention;

FIG. 4B is an exploded perspective view of the semiconductor package module shown in FIG. 4A;

FIG. 5A is a perspective view schematically showing a semiconductor package module according to another exemplary embodiment of the present invention;

FIG. 5B is an exploded perspective view of the semiconductor package module shown in FIG. 5A; and

FIG. 6 is a cross-sectional view showing a semiconductor package module according to another exemplary embodiment of the present invention.

### DETAILED DESCRIPTION OF THE PREFERRED EMBODIMENT

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention. Therefore, the configurations described in the embodiments and drawings of the present invention are merely the most preferable embodiments, but do not represent the overall technical spirit of the present invention. Thus, the present invention should be construed as including all of the changes, equivalents, and substitutions included in the spirit and scope of the present invention at the time of filing this application.

Hereinafter, exemplary embodiments of the present invention will be described in detail with reference to the accompanying drawings. In the drawings, like reference numerals denote like elements. Moreover, detailed descriptions related to well-known functions or configurations will be ruled out in order not to unnecessarily obscure the subject matter of the present invention. For the same reason, it is to be noted that some components shown in the drawings are exaggerated, omitted or schematically illustrated, and the size of each component does not exactly reflect its actual size.

Hereinafter, exemplary embodiments of the present invention will be described in detail with reference to the accompanying drawings.

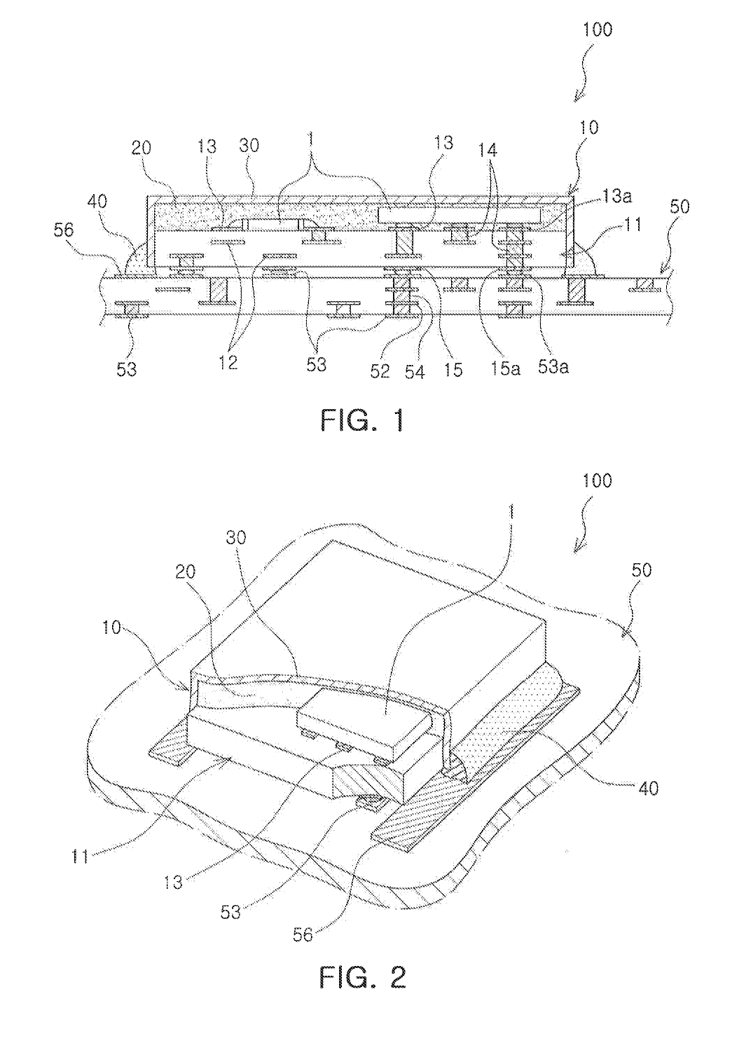

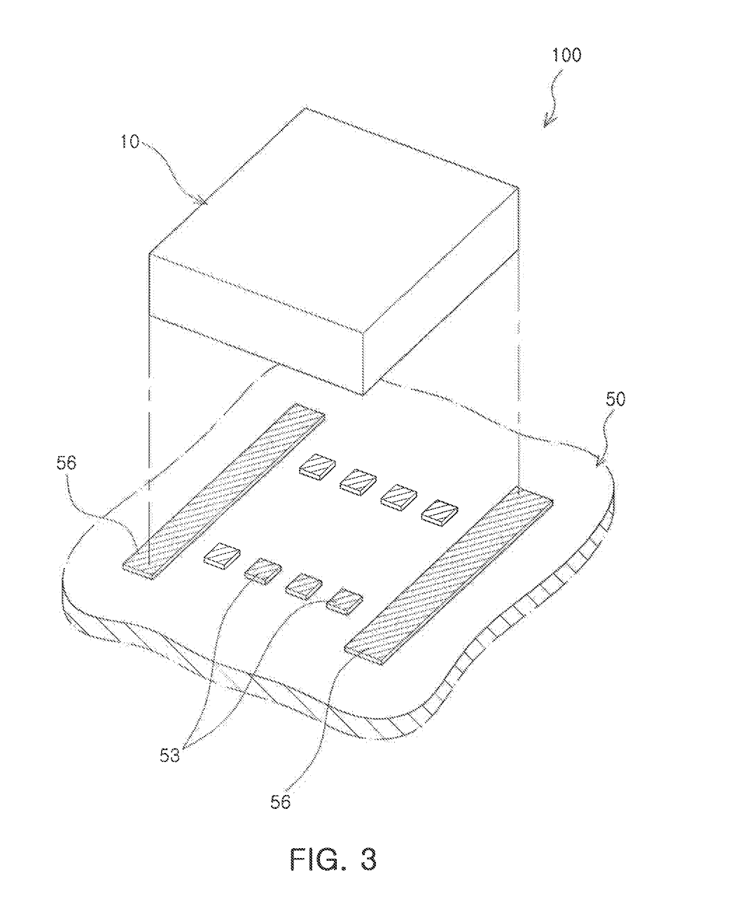

FIG. 1 is a cross-sectional view showing a semiconductor package module according to an exemplary embodiment of the present invention. In addition, FIG. 2 is a cut-away perspective view showing an inner portion of the semiconductor package module shown in FIG. 1 and FIG. 3 is an exploded perspective view of the semiconductor package module shown in FIG. 2.

As shown in FIGS. 1 to 3, a semiconductor package module 100 according to an exemplary embodiment of the present invention is configured to include a semiconductor package 10 and a main substrate 50 having the semiconductor package 10 mounted thereon.

The semiconductor package 10 is configured to include, a substrate 11, electronic components 1, a molding part 20, and a shield 30.

The substrate 11 has at least one electronic component 1 mounted on an upper surface thereof. As the substrate 11, various kinds of substrates (for example, a ceramic substrate, a printed circuit board (PCB), a flexible substrate, or the like) well known in the art may be used.

Mounting electrodes 13 for mounting the electronic components 1 or wiring patterns (not shown) electrically interconnecting the mounting electrodes 13 may be formed on the upper surface of the substrate 11. In addition, the mounting electrode 13 may include at least one ground electrode 13a electrically connected to ground terminals (not, shown) of the electronic components 1.

Further, the substrate 11 according to an exemplary embodiment of the present invention may be a multilayer substrate including a plurality of layers, and circuit patterns 12 for forming electrical connections may be formed between the plurality of individual layers. These circuit, patterns 12 may include ground patterns electrically connected to the ground electrode 13a.

In addition, the substrate 11 according to an exemplary embodiment of the present invention may include external connection terminals 15 electrically connected to the mounting electrodes 13 formed on the upper surface thereof, the circuit patterns 12 formed in an inner portion thereof, and the like, and conductive via-holes 14 electrically connecting the mounting electrodes 53 and the circuit patterns 52. Further, the external connection terminals 15 may include at least one external ground terminal 15a electrically connected to the ground pattern.

Furthermore, the substrate 11 according to an exemplary embodiment of the present invention may have a cavity (not shown) capable of mounting the electronic components 1 in the inner portion thereof.

The electronic components 1 include various elements such as passive elements and active elements, and all of the elements capable of being mounted on the substrate 11 or capable of being embedded in the inner portion of the substrate 11 may be used as the electronic components 1.

The molding part 20 is provided between the substrate 11 and the shield 30 to seal the electronic components 1. The molding part 20 is provided between the electronic components 1 mounted on the substrate 11, thereby preventing electrical short-circuits from being generated between the electronic components 1. In addition, the molding part 20 encloses the outside of the electronic components 1 and fixes the electronic components 1 to the substrate to securely protect the electronic components 1 from external shocks. The molding part 20 may be made of an insulating material including a resin material such as epoxy, or the like.

The shield 30 receives the electronic components 1 therein and is coupled to the substrate 11 to shield unnecessary electromagnetic waves introduced from the outside. In addition, the shield 30 shields electromagnetic waves generated in the electronic components 1 from being radiated to the outside. The shield 30 is closely adhered to the molding part 20 and is formed to cover an outer surface of the molding part 20.

The shield 30 is inevitably grounded in order to shield the electromagnetic waves. However, in the semiconductor package 10 according to an exemplary embodiment of the present invention, the shield 30 is not electrically connected directly to the ground pattern formed on the substrate 11 of the semiconductor package 10. That is, the shield 30 according to an exemplary embodiment the present invention is coupled to the substrate 11 to be electrically insulated from the circuit patterns 12, the mounting electrodes 13, or the external connection terminals 15 which are formed on the substrate 11.

On the other hand, shield 30 according to an exemplary embodiment of the present invention is electrically connected directly to a ground pad 56 of the main substrate 50 described below. The shield 30 and the ground pad 56 of the main substrate 50 are bonded to each other by a bonding part 40. A detailed description thereof will be provided in description of the bonding part 40 below.

The shield 30 according to an exemplary embodiment of the present invention may be made of various materials and may have the form of a metal case. However, the present invention is not limited thereto. That is, the shield 30 according to an exemplary embodiment of the present invention may be manufactured by applying a resin material including conductive powders to the outer surface of the molding part 20 or forming a metal thin film. When the metal thin film is formed, various methods such as a sputtering method, a vapor deposition method, an electroplating method, an electroless plating method may be used.

In addition, the shield 30 may be a metal thin film formed on the outer surface of the molding part 20 by using a spray coating method. The spray coating method has advantages in that it may form a uniformly applied film and is relatively inexpensive as compared to other processes. In addition, the shield 30 may be a metal thin film formed through a screen printing method.

The main substrate 50 has at least one semiconductor package 10 mounted on a surface thereof and electrically connected thereto. In addition, the main substrate 50 has various electronic components, in addition to the semiconductor package 10, mounted thereon.

The main substrate 50 according to an exemplary embodiment of the present invention may be a general printed circuit board (PCB) provided in electronic products and may be a module substrate having a plurality of semiconductor packages 10 mounted thereon.

Similar to the substrate 11 provided in the semiconductor package 10, various kinds of substrates (for example, a ceramic substrate, a printed circuit hoard, a flexible substrate, or the like) well known in the art may be used as the main substrate 50.

In addition, mounting electrodes 53 for mounting the electronic components 1 or wiring patterns (not shown) electrically interconnecting the mounting electrodes 53 may be formed on the upper surface of the main substrate 50 with. In addition, the mounting electrode 53 may include a ground electrode 53a electrically connected to the external ground terminals 15a of the electronic components 1.

The main substrate 50 according to an exemplary embodiment of the present invention may be a multilayer substrate including a plurality of layers, and circuit patterns 52 for forming electrical connections may be formed between the plurality of individual layers. These circuit patterns 52 may include ground patterns (not shown) electrically connected to the ground electrode 53a.

Further, the ma in substrate 50 according to an exemplary embodiment of the present invention may include the mounting electrodes 53 formed on the upper surface thereof, the circuit patterns 52 formed in an inner portion thereof, and conductive via-holes 54 electrically connecting the mounting electrodes 53 and the circuit patterns 52. In addition, the main substrate 50 according to an exemplary embodiment of the present invention may have a cavity (not shown) capable of mounting the electronic components in the inner portion of the main substrate 50.

In addition, the main substrate 50 according to an exemplary embodiment of the present invention includes the ground pads 56 formed on the upper surface thereof. The ground pads 56 may be formed to correspond to an outer edge of the semiconductor package 10 mounted on the main substrate 50.

According to an exemplary embodiment of the present invention, a case in which the ground pads 56 have an elongated bar shape along the outer edge of the semiconductor package 10 on the upper surface of the main substrate 50 is described by way of example. However, the main substrate 50 according to an exemplary embodiment of the present invention is not limited thereto. That is, the ground pads 56 according to an exemplary embodiment of the present invention may have a ring shape (for example, a rectangular ring shape), or may have various shapes as those in another exemplary embodiment of the present invention to be described below.

In addition, according to an exemplary embodiment of the present invention, a case in which all of the ground pads 56 have the same width on the main substrate 50 is described by way of example. However, the present invention is not limited thereto. That is, each of the ground pads 56 may have different widths.

The bonding part 40 electrically connects the shield 30 to the ground pads 56 of the main substrate 50, as described above. At this time, the bonding part 40 serves to bond the shield 30 to the main substrate 50 to fixedly couple the semiconductor package 10 to the main substrate 50.

The bonding part 40 according to an exemplary embodiment of the resent invention may be made of various materials having conductivity, similar to the shield 30. For example, the bonding part 40 may be made of a conductive adhesive, a conductive solder, or the like. A resin material including conductive powders may be used as the conductive adhesive, and a lead-free solder including Sn and Ag may be used as the solder. However, the present invention is not limited thereto.

The bonding part 40 may be formed by applying the conductive adhesive or the conductive solder in a paste state to the ground pad 56 of the main substrate 50, seating the semiconductor package 10 thereon, and then curing the conductive adhesive or the conductive solder.

The semiconductor package module 100 according to an exemplary embodiment of the present invention configured as described above may not only protect the electronic components 1, mounted on the substrate 11 by the molding part 20, from external force, but may also further improve an electromagnetic wave shielding effect by the shield 30 formed on the outer surface of the molding part 20.

In addition, in the semiconductor package module 100 according to an exemplary embodiment of the present invention, the shield 30 is directly connected to the ground pad 56 formed on the upper surface of the main substrate 50, without being electrically connected to the ground pattern or the ground electrode 13a provided on the substrate 11 of the semiconductor package 10.

Therefore, the shield 30 of the semiconductor package 10 may be grounded only using a process of mounting the semiconductor package 10 on the main substrate 50.

Accordingly, when the semiconductor package 10 is manufactured, various existing processes that have been separately performed in order to electrically connect the shield 30 to the ground electrode 13a or the external ground terminal 15a of the substrate 11 may be omitted, such that the semiconductor package 10 and the semiconductor package module 100 may be manufactured more easily and faster, as compared to those of the related art. In addition, since several processes may be omitted, manufacturing costs may be significantly reduced, as compared to the related art,

Further, in the semiconductor package module 100 according to an exemplary embodiment of the present invention, since the shield 30 is bonded to the ground pad 56 of the main substrate 50 by the bonding part 40, the shield 30 and the main substrate 50 are electrically interconnected using a very wider area, as compared to the case according to the related art in which the bonding of shield is performed by using a circuit pattern or a terminal. Accordingly, damage to the bonded portion due to shocks or the like, may be minimized, whereby bonding reliability between the shield and the main substrate 50 may be secured.

The semiconductor package module 100 according to an exemplary embodiment of the present invention is not limited to the above-mentioned exemplary embodiment, but may be variously modified. A semiconductor package module according to another exemplary embodiment of the present invention to be described below is configured to have a similar structure to the semiconductor package module 100 according to the above-mentioned exemplary embodiment of the present invention, with the exception of a difference in the shape of the main substrate and the shield. Accordingly, a detailed description of the same components will be omitted, and the main substrate and the shield will be mainly described in detail. In addition, the same reference numerals will be used to designate the same or like elements as those in the abovementioned exemplary embodiment of the present invention.

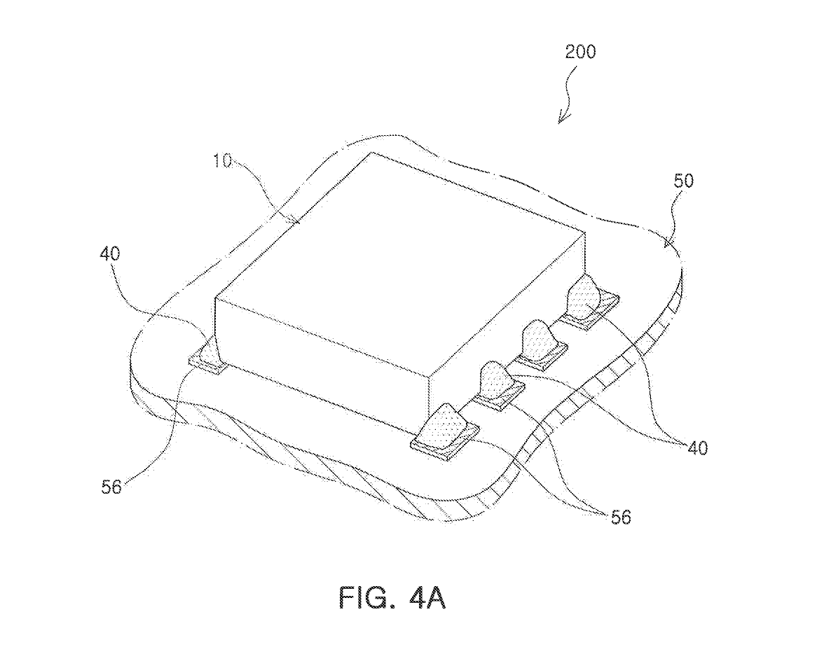

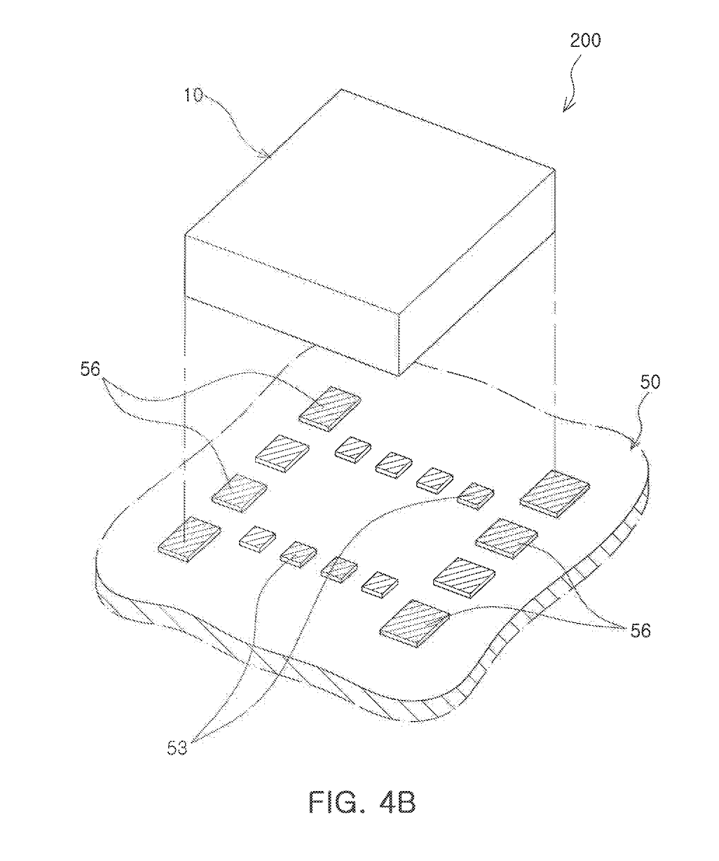

FIG. 4A is a perspective view schematically showing a semiconductor package module according to another exemplary embodiment of the present invention, and FIG. 4B is an exploded perspective view of the semiconductor package module shown in FIG. 4A. Referring to FIGS. 4A and 4B, a semiconductor package module 200 according to another exemplary embodiment of the present invention is configured similarly to the semiconductor package module 100 (in FIG. 1) according to the above-mentioned exemplary embodiment of the present invention, with the exception of a difference in the shape of the ground pads 56 formed on the main substrate 50.

That is, while the ground pad 56 of the main substrate 50 in the above-mentioned exemplary embodiment of the present invention shown in FIG. 2 has an elongated bar shape along the outer edge of the semiconductor package 10, a plurality of ground pads 56 of the main substrate 50 according to the present embodiment are arranged in a row alone: the outer edge of the semiconductor package 10.

Such a configuration, in which the plurality of ground pads 56 are arranged in this manner, may be advantageously used when wiring patterns (not shown), formed on the main substrate 50, should be formed to traverse the ground pads 56.

In addition, the configuration of the ground pads according to this exemplary embodiment oil the present invention may minimize the amount of the solder paste or the conductive adhesive used for bonding the semiconductor package 10 to the main substrate 50, as compared to the above-mentioned exemplary embodiment of the present invention.

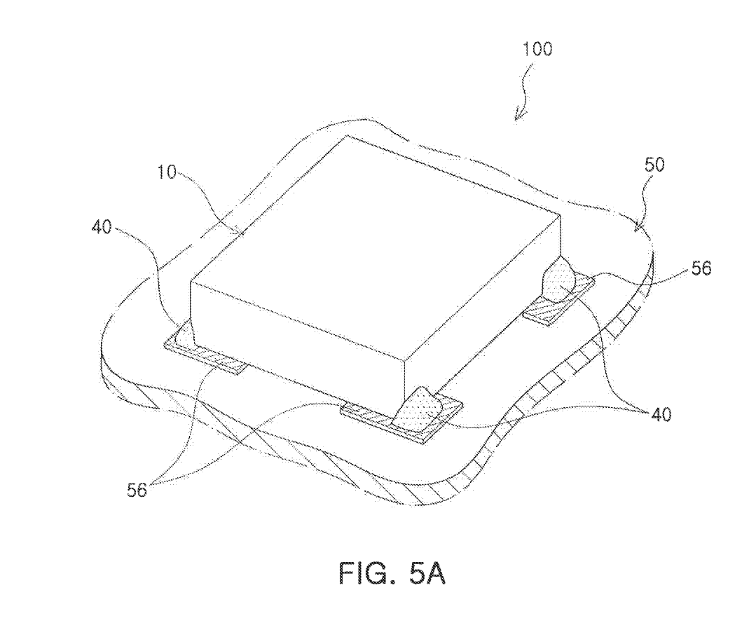

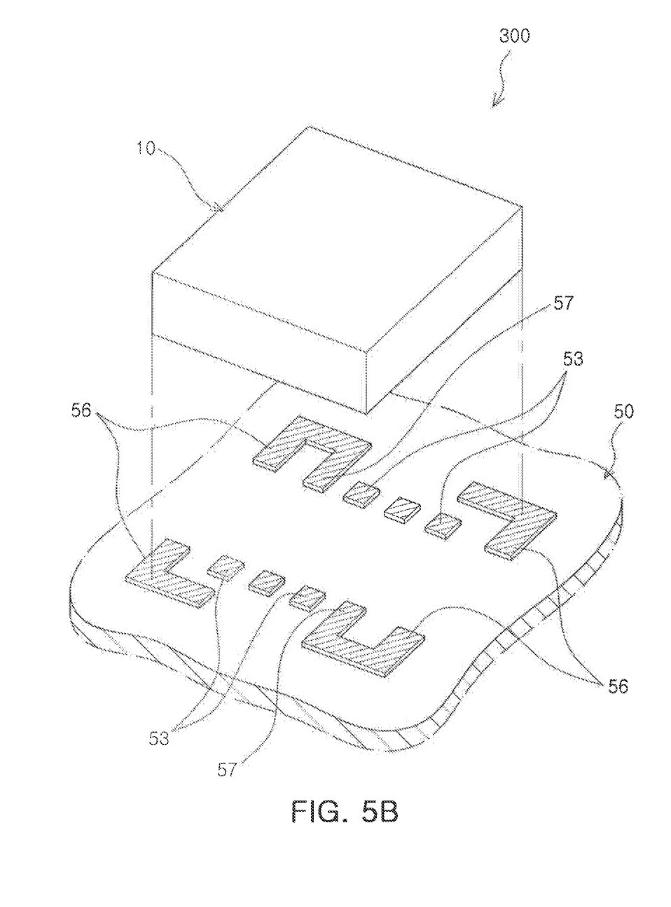

FIG. 5A is a perspective view schematically showing a semiconductor package module according to another exemplary embodiment of the present invention, and FIG. 5B is an exploded perspective view of the semiconductor package module shown in FIG. 5A. Referring to FIGS. 5A and 5B, a semiconductor package module 200 according to another exemplary embodiment of the present invention is configured similarly to the semiconductor package module 100 (in FIG. 1) according to the above-mentioned exemplary embodiment of the present invention, with the exception of a difference in the shape of the ground pads 56 formed on the main substrate 50.

That is, while the ground pad 56 of the main substrate 50 in the exemplary embodiment of the present invention shown in FIG. 2 has an elongated has shape along the outer edge of the semiconductor package 10, each of a plurality or ground pads 56 of the main substrate 50 according to the present embodiment is disposed at a corner of the semiconductor package 10 along the outer edge of the semiconductor package 10. Accordingly, the shield 30 of the semiconductor package 10 according to this exemplary embodiment of the present invention is bonded to the ground pads 56 of the main substrate 50 only at the corners thereof.

Further, the ground pads 56 according to the present embodiment may include a protrusion part 57 which is at least one portion of the ground pad protruding inwardly of the outer edges of semiconductor package 10 such that the protrusion part 57 may be disposed, therebelow.

The protrusion part 57 is electrically connected to the external ground terminal 15a provided on the substrate 11 of the semiconductor package 10. To this end, the protrusion part 57 according to this exemplary embodiment is protruded to a position in which the external ground terminal 15a of the semiconductor package 10 is disposed, when the semiconductor package 10 is mounted on the main substrate 50.

In the case in which the ground pads 56 include the protrusion part 57 as described above, the shield 30 and the external ground terminal of the substrate 11 are simultaneously bonded to the ground pads 56, whereby the shield 30, the substrate 11, and the ground pattern of the main substrate 50 are electrically interconnected using only a process of mounting the semiconductor package 10 on the main substrate 50. Accordingly, the reliability of the ground pattern may be secured.

Meanwhile, the protrusion part 57 of the ground pad 56 is not limited to this exemplary embodiment of the present invention in which the grouch pads are provided at the corners, but may be easily applied to the ground pads 56 according to the above-mentioned exemplary embodiments of the present invention.

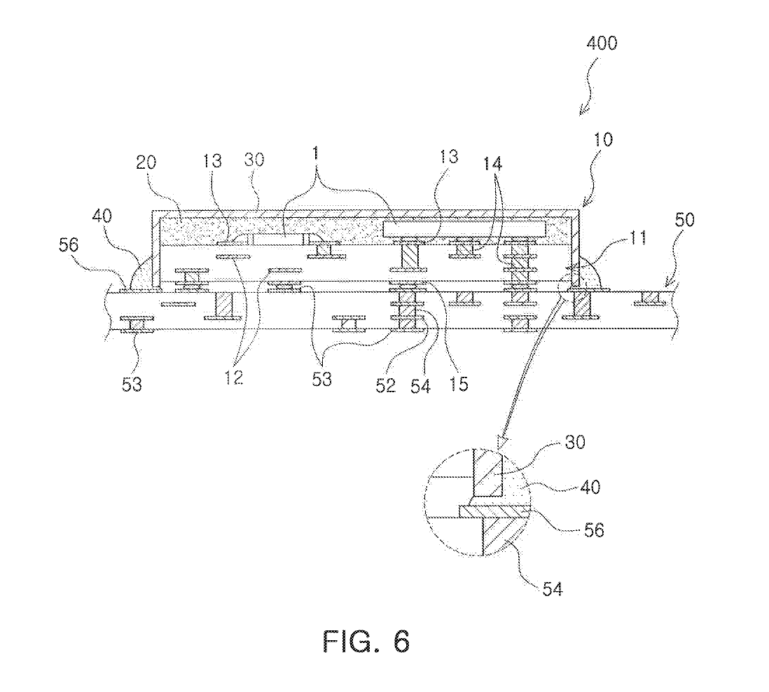

FIG. 6 an cross-sectional view showing a semiconductor package module according to another exemplary embodiment of the present invention. Referring to FIG. 6, a semiconductor package module 400 according to another exemplary embodiment of the present invention is configured similarly to the semiconductor package module 100 (in FIG. 1) according to the above-mentioned exemplary embodiment of the present invention as described above, with the exception of a difference in the shape of the shield 30 included in the semiconductor package 10.

That is, while ends of side walls of the shield 30 are disposed on the same plane as the lower surface of the substrate 11 in the above-mentioned exemplary embodiment of the present invention shown in FIG. 2, ends of side walls of the shield 30 according to the present embodiment are protruded downwardly of the lower surface of the substrate 11.

Here, a distance, by which the shield 30 is protruded downwardly of the lower surface of the substrate 11, is determined to correspond to a distance from the lower surface of the semiconductor package 10 to the upper surface or the main substrate 50. That is, the ends of the side walls of the shield 30 according to this embodiment are protruded by a distance equal to or slightly shorter than the distance from the lower surface of the semiconductor package 10 to the upper surface of the main substrate 50.

Accordingly, in the semiconductor package 10 according to this embodiment, the ends of the side walls of the shield 30 are in contact with the upper surface of the main substrate 50 (that is, the ground pads) or are disposed adjacently thereto to thereby be bonded to the ground pads 56 of the main substrate 50. Therefore, the bonding reliability between the shield 30 and the around pads 56 may be further enhanced.

In addition, at least one of the side walls of the shield 30 according to the present embodiment may be protruded downwardly of the substrate 11, or only portions thereof corresponding to the ground pads 56 rather than the entire side walls may be partially protruded.

The shield 30 according to this embodiment may be formed as a metal case.

The invention is not limited to the above-mentioned exemplary embodiments, but may be variously modified. For example, a molding part is included in a semiconductor package in the above-mentioned exemplary embodiments of the present invention; however, the molding part may be omitted as needed.

In addition, a semiconductor package having a shield is mounted on a main substrate in the above-mentioned exemplary embodiments of the present invention; however, the present invention is not limited thereto. It may be variously applied to any apparatuses including a shield for shielding electromagnetic waves.

As set forth above, in a semiconductor package module according to exemplary embodiments of the present invention, a shield is directly connected to a ground pad formed on an upper surface of a main substrate, without being electrically connected to a ground pattern or a ground electrode provided in a substrate of a semiconductor package.

Therefore, the shield of the semiconductor package may be grounded using only a process of mounting the semi conductor package on the main substrate.

Accordingly, when the semiconductor package is manufactured, various existing processes that have been separately performed in order to electrically connect the shield to the ground electrode or an external ground terminal of the substrate may be omitted, such that the semiconductor package and the semiconductor package module may be manufactured more easily and faster, as compared to those of the related art. In addition, since several processes may be omitted as described above, manufacturing costs may be significantly reduced, as compared to the related art.

Further, in the semiconductor package module according to the exemplary embodiments of the present invention, since the shield is bonded to the ground pad of the main substrate by a bonding part, the shield and the main substrate are electrically interconnected using a very wider area, as compared to the case according to the related art in which the bonding of the shield is performed by using a circuit pattern or a terminal.

Accordingly, the damage to the bonded portion due to external shocks or the like, may be minimized, Whereby bonding reliability between the shield and the main substrate may be secured.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor package module comprising:
a semiconductor package having a shield formed on an upper surface thereof and side surfaces thereof;
a main substrate having at least one ground pad formed on a surface thereof and having the semiconductor package mounted thereon; and
a bonding part bonding the ground pad to the shield to electrically connect the ground pad to the shield.

2. The semiconductor package module of claim 1, wherein the ground pad is disposed along an outer edge of the semiconductor package.

3. The semiconductor package module of claim 1, wherein the ground pad has an elongated bar shape along an outer edge of the semiconductor package.

4. The semiconductor package module of claim 1, wherein the ground pad comprises a plurality of ground pads arranged in a row along an outer edge of the semiconductor package.

5. The semiconductor package module of claim 1, wherein the ground pad comprises a plurality of ground pads each arranged in a corner of the semiconductor package along an outer edge of the semiconductor package,

6. The semiconductor package module of claim 1, wherein the ground pad includes a protrusion part protruding in an inward manner so as to be disposed below the semiconductor package, the protrusion part being electrically connected to at least one external connection terminal provided on the semiconductor package.

7. The semiconductor package module of claim 1, wherein the semiconductor package comprises:
a substrate; and
at least one electronic component mounted on a surface of the substrate,
wherein the shield has the electronic component received therein and is coupled to the substrate so as to be electrically insulated from a circuit pattern formed on the substrate.

8. The semiconductor package module of claim 7, further comprising an insulating molding part sealing to space between the substrate and the shield.

9. The semiconductor package module of claim 7, wherein the shield has at least one side wall protruding downwardly of the substrate.

10. The semiconductor package module of claim 9, wherein a portion of a side wall of the shield, corresponding to a position of the ground pad formed on the main substrate, protrudes downwardly of the substrate.

11. The semiconductor package module of claim 9, wherein a distance, by which the shield is protruded downwardly of the substrate, corresponds to a distance from a lower surface of the semiconductor package to an upper surface of the main substrate.
